(19) United States
(12) Patent Application Publication
(10) Pub. No.: US 2007/0138538 A1
(43) Pub. Date: Jun. 21, 2007

(54) Method of forming self-aligned floating gate array and flash memory device including self-aligned floating gate array

(75) Inventor: Jong Woon Choi, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/643,405

(22) Filed: Dec. 19, 2006

(30) Foreign Application Priority Data
Dec. 20, 2005 (KR) 10-2005-0126032

(51) Int. Cl. H01L 29/788; H01L 21/336

(52) U.S. Cl. 257/315; 438/257

(57) ABSTRACT

Disclosed are a flash memory device including a self aligned floating gate array, and a method of forming the self aligned floating gate array for the flash memory device. The flash memory device includes a plurality of device isolation layers formed by the oxidation of a silicon substrate, and a floating gate array formed in active device regions divided by the plurality of device isolation layers and in which sidewalls of the floating gate are self aligned to the plurality of device isolation layers. Therefore, it is possible to minimize the width of the device isolation regions regardless of the minimum line width as defined by process design rules.

This application claims the benefit of Korean Application No. 10-2005-0126032, filed on Dec. 20, 2005, which is incorporated by reference herein in its entirety.

### BACKGROUND OF THE INVENTION

1. Field of the Invention

The present invention relates to a method of manufacturing a semiconductor device. More specifically, the present invention relates to a floating gate array of a flash memory device and a method of manufacturing the same.

2. Description of the Related Art

A flash memory is a kind of PROM (programmable ROM) capable of electrically re-writing data. The flash memory can include an erasable PROM (EPROM) and an electrically erasable PROM (EEPROM). A flash memory can combine the advantages of an EPROM, in which a memory cell includes one transistor so that a cell area is small, and an EEPROM, in which data can be electrically erased. However, data must be erased in an EPROM by UV rays, and an EEPROM cell usually includes two transistors so that a cell area becomes large. Another name for the flash memory is a flash EEPROM. The flash memory is referred to as a nonvolatile memory since stored information is not erased although power is turned off, which is different from a dynamic RAM (DRAM) or a static RAM (SRAM).

The flash memory may be a NOR-type structure in which cells are arranged in a row (in parallel) between a bit line and a ground or a NAND-type structure in which cells are arranged in series between the bit line and the ground. Since the NOR-type flash memory having the parallel structure can perform high speed random access when a reading operation is performed, the NOR-type flash memory is widely used for booting a mobile telephone. The NAND-type flash memory having the serial structure has low reading speed but high writing speed so that the NAND-type flash memory is suitable for storing data and is advantageous for miniaturization. The flash memory also includes a stack gate type and a split gate type in accordance with the structure of a unit cell, and can also include a floating gate device and a silicon-oxide-nitride-oxide-silicon (SONOS) device in accordance with the shape of and/or materials used in a charge storage layer.

Among them, the floating gate device includes floating gates including polycrystalline silicon, surrounded by an insulating substance. Charges are implanted into or discharged from the floating gates by channel hot carrier injection or Fowler-Nordheim (F-N) tunneling so that data can be stored and erased.

FIG. 1 illustrates a section of a semiconductor substrate where a floating gate array is formed in a process of manufacturing a flash memory device. The section of the substrate illustrated in FIG. 1 is perpendicular to the bit line of the flash memory device. In the conventional flash memory device, a series of device isolation layers 22, for example, shallow trench isolations (STI) are formed in a substrate 10 in the direction perpendicular to a word line to define an active device region. Then, a silicon oxide layer 12 used as a tunnel oxide layer is formed to a predetermined thickness on the entire (exposed) surface of the substrate, and a polycrystalline silicon layer to be used as the floating gate is formed. Such a polycrystalline silicon layer is patterned through a photolithography process and an etching process to form a plurality of floating gates, or a floating gate array 26.

The floating gates 26 constitute part of a memory cell, in which adjacent floating gates are separated from each other by a distance W. Since floating gates 26 are commonly patterned through the photolithography process and the etching process, it is not easy to reduce the distance W beyond the limitation of the photolithography process. Also, in order to improve the integrity of the device, the device isolation layers 22 for insulating adjacent memory cells as well as the distance between the floating gates 26 should be narrow. However, since the device isolation regions are patterned through the photolithography process in the common STI forming process, it is difficult to reduce the size of the device isolation layers 22 and the distance between the floating gates 26 to less than a predetermined size (often referred to as a “critical dimension”). As described above, when the formation of the floating gates 26 and the STI depend on the photolithography process, expensive exposure equipment must be used, resulting in an increased manufacturing cost.

Furthermore, in the processes of manufacturing the conventional flash memory device, as described above, the STI is formed in the substrate, and then the floating gates are patterned through an additional photolithography process. In order to prevent the misalignment of etching masks in the process of forming floating gates, a minimum alignment margin must be ensured. Therefore, since the width of the STI and the distance between floating gates must be maintained in a predetermined level, it is not possible to improve the integrity of the device if the photolithography process is solely performed.

### SUMMARY OF THE INVENTION

The present invention has been made to solve the above problem(s), and therefore, it is an object of the present invention to provide a highly integrated flash memory device capable of significantly reducing the width of device isolation layers and the distance between floating gate electrodes without being limited by the minimum line width of a photolithography process.

It is another object of the present invention to provide a method of forming device isolation layers and a self aligned floating gate array by simultaneously forming the device isolation layers and the floating gates through one process.

According to one aspect of the present invention, there is provided a method of forming a self aligned floating gate array. The method may include the steps of (a) forming a continuous oxide layer and a first sacrificial (e.g., nitride) layer on a silicon substrate, (b) etching the first sacrificial layer to form a first sacrificial layer pattern, (c) forming first spacers (e.g., comprising an oxide) on the sidewalls of the first sacrificial layer pattern, (d) selectively removing the first sacrificial layer pattern, (e) forming a second sacrificial layer pattern divided by the first spacers on the substrate, (f) removing the first spacers between the second sacrificial layer pattern structures to expose the surface of the substrate between the second sacrificial layer pattern structures, (g) etching the surface of the exposed substrate to a predetermined depth to form trenches in the substrate, (h) oxidizing the exposed surface of the substrate to form device isolation layers in the substrate, (i) forming second spacers between the second sacrificial layer pattern structures, (j) selectively removing the second sacrificial layer pattern, and (k) forming a plurality of floating gates divided by the second spacer.

A flash memory device including the self aligned floating gate array (e.g., formed by the above method) may include a plurality of device isolation layers comprising a thermal silicon oxide in the substrate, and a floating gate array which in active device regions divided by the plurality of device isolation layers and in which sidewalls of each floating gate are self aligned to the device isolation layers.

### BRIEF DESCRIPTION OF DRAWINGS

FIG. 1 is a sectional view illustrating a floating gate array of a conventional flash memory device;

FIGS. 2 to 12 are sectional views illustrating processes of a method of forming a self aligned floating gate array according to the present invention, in order; and

FIG. 13 is a sectional view of a flash memory device including the self-aligned floating gate array according to the present invention.

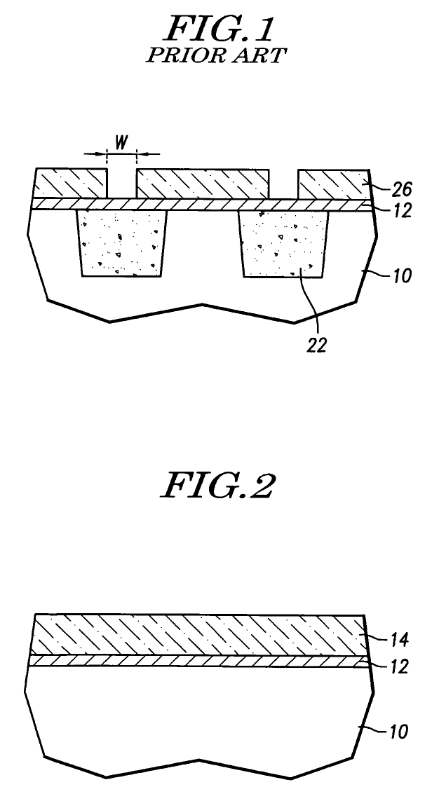

### DETAILED DESCRIPTION OF THE INVENTION

Preferred embodiments of a flash memory device including a self aligned floating gate array according to the present invention and a method of forming the self aligned floating gate array will be described in detail with reference the attached drawings.

### Embodiment 1

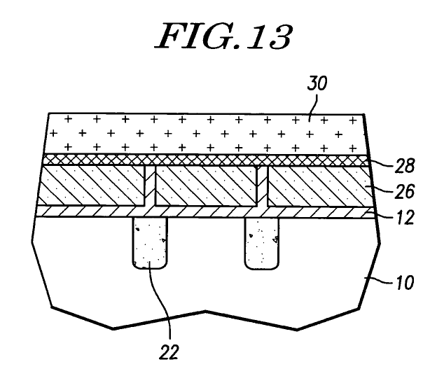

FIG. 13 illustrates a flash memory device including a self aligned floating gate array according to the present invention. FIG. 13 illustrates the section perpendicular to the bit line of the flash memory device.

Referring to FIG. 13, the flash memory device includes a stack gate comprising floating gates 26, an insulator layer such as an oxide-nitride-oxide (ONO) dielectric layer 28, and a control gate 30. Here, device isolation layers 22 insulate adjacent memory cells formed in a substrate 10.

In particular, the device isolation layers 22 are not formed by a common STI manufacturing method, but rather, by oxidizing a silicon substrate. Also, the device isolation layers 22 are formed the same photolithographic process as the floating gates 26. As a result, the sidewalls of the floating gate 26 are self aligned to the device isolating layer 22.

### Embodiment 2

Hereinafter, processes of forming the self aligned floating gate array for the flash memory device according to the present invention will be described with reference to FIGS. 2 to 12. Here, FIGS. 2 to 12 illustrate the section perpendicular to the bit line of the flash memory device.

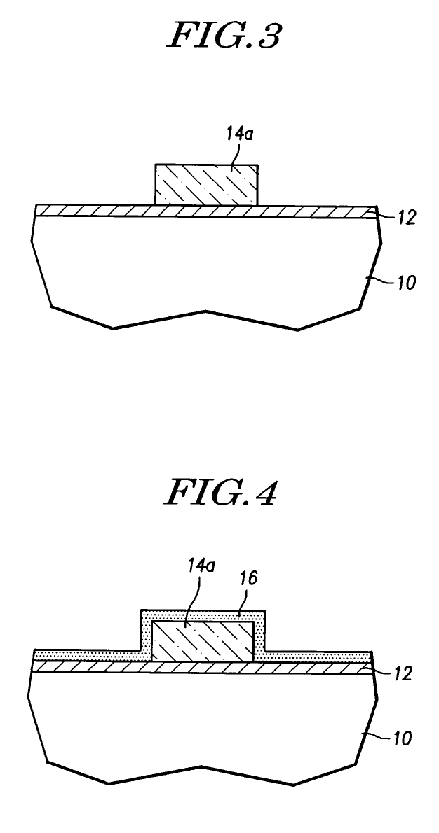

First, referring to FIG. 2, a first oxide layer 12 and a first sacrificial (e.g., silicon nitride) layer 14 are continuously formed on the silicon semiconductor substrate 10. The first (silicon) oxide layer 12 is used as the tunnel oxide layer of the flash memory cell, and may be formed by conventional wet or dry thermal oxidation or by conventional chemical vapor deposition. Then, as illustrated in FIG. 3, the first nitride layer 14 is patterned through a photolithography process and an etching process. A single nitride layer pattern structure 14a is formed only in an active device region of one or more (e.g., two) adjacent memory cells. A flash memory cell array may be arranged in a line, while a plurality of cells is insulated by the device isolation layers. The first nitride layer pattern 14a may thus be formed only in a cell region between two adjacent cell regions. However, the active regions in the row direction may alternate (e.g., the area in which the first nitride pattern 14a is formed and a region between adjacent first nitride pattern structures 14a are alternately arranged). As it will be understood from a subsequent description, the region in which the first nitride pattern 14a is formed and the adjacent region(s) in which the first nitride pattern 14a is not formed are unit cell regions. A boundary of the first sacrificial (nitride) pattern 14a is the device isolation region.

Then, as illustrated in FIG. 4, a second (e.g., oxide) layer 16 is deposited on the entire surface of the substrate 10. Then, when an anisotropic etching process is performed on the entire surface of the substrate 10 (without using a mask), second oxide layer spacers 16a are formed on the sidewalls of the first nitride layer pattern 14a as illustrated in FIG. 5. After anisotropically removing the second oxide layer 16 (excluding the second oxide layer spacers 16a), the first nitride layer pattern 14a is selectively removed through an additional process. The selective removal of the first nitride layer pattern 14a can be performed through a wet etching process using a phosphoric acid solution. Alternatively, the first sacrificial pattern may comprise polysilicon or another material that can be selectively etched or removed, relative to the first spacer material. For example, the first sacrificial pattern may comprise a silicon oxide, and the first spacer material may comprise silicon nitride.

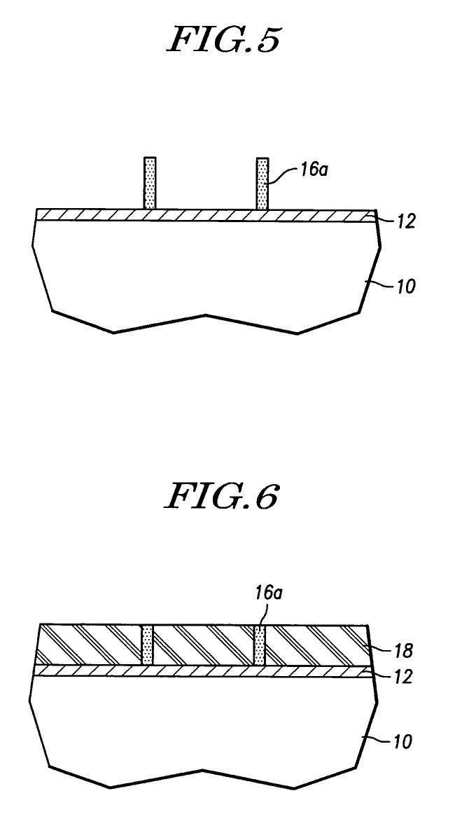

Next, after a second sacrificial (e.g., nitride) layer is deposited to a sufficient thickness on the substrate 10 to fill the spaces or gaps between the second oxide layer spacers 16a, the upper portion of the second sacrificial (e.g., nitride) layer is planarized until the upper ends of the second oxide layer spacers 16a are exposed (for example, using a chemical-mechanical polishing process). Then, as illustrated in FIG. 6, a (plurality of) second sacrificial (e.g., nitride) layer pattern structures 18, divided by the second oxide layer spacers 16a, are formed.

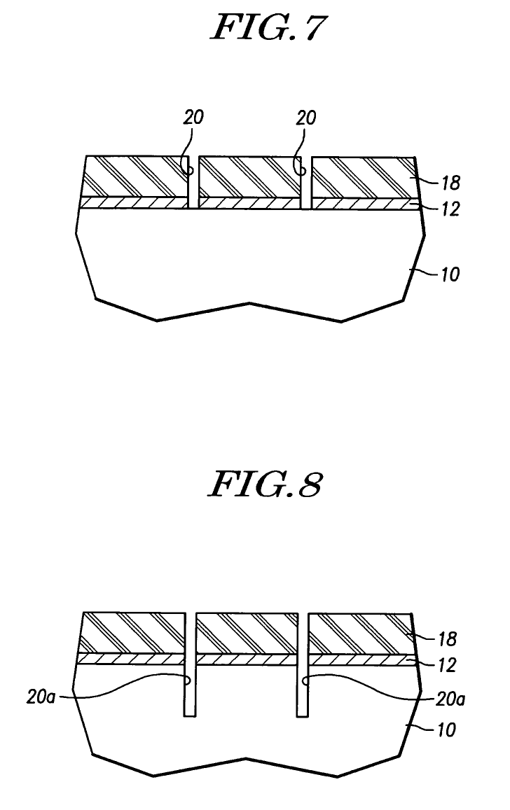

After that, the second oxide layer spacers 16a between the second nitride layer pattern structures 18 are removed. In the process of removing the second oxide layer spacers 16a, only the oxide is selectively etched. In order to completely remove the oxide in the narrow gaps among the second nitride layer patterns 18, a wet etching solution having high etching selectivity ratio with respect to the nitride layer is used. When the second oxide layer spacers 16a are removed by wet etching, as illustrated in FIG. 7, the surface of the substrate 10 is exposed in the gaps 20 between the nitride layer pattern structures 18.

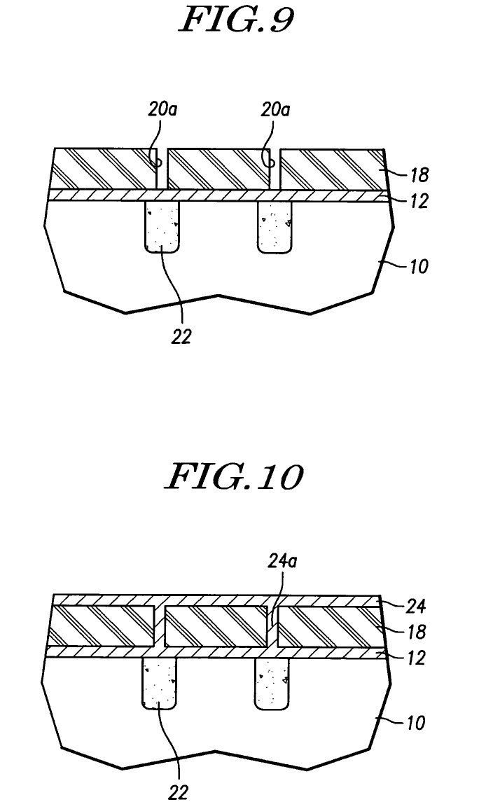

Then, as illustrated in FIG. 8, the surface of the substrate exposed by the gaps 20 is etched to a predetermined depth using the second nitride layer pattern 18 as an etching mask to form trenches 20a in the substrate 10. The predetermined depth may be from 1000 to 5000 Å, preferably about 1500 to about 4000 Å. Then, the surfaces (the internal walls of the trenches 20a) of the substrate 10 exposed by the trenches 20a are oxidized. The oxidation process preferably comprises a silicon oxidation process (e.g., wet or dry thermal oxidation) so that the silicon on the internal walls of the trenches 20 is oxidized and effectively fills the trenches 20a (refer to FIG. 9). Such oxide layers function as the device isolation layers 22 that insulate the memory cells from each other.

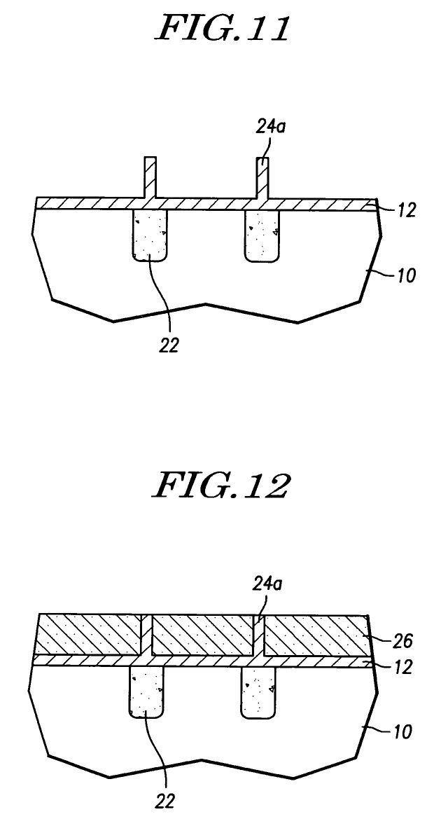

Next, as illustrated in FIG. 10, the gaps 20a formed between the second nitride layer patterns 18 are filled with a third oxide layer. At this time, the third oxide layer 24 may be formed by a chemical vapor deposition (CVD) process having a high gap fill characteristics (e.g., high density plasma-assisted [HDP] CVD) and is formed in the gaps and on the second nitride layer pattern 18. Then, in order to remove the third oxide layer deposited on the second nitride layer pattern 18, a planarization process (e.g., by an etch back or chemical mechanical polishing process) is performed. Thereafter, the second nitride layer pattern 18 is selectively removed using a phosphoric acid solution having a high etching selectivity ratio with respect to the oxide layer. Then, as illustrated in FIG. 11, a part of the third oxide layer buried in the gaps 20a among the second nitride layer patterns 18 remains to form spacers 24a.

Finally, floating gates 26 are formed on the oxide layer 12 on the substrate 10 and in the regions divided by the third oxide layer spacers 24a. The floating gates 26 preferably comprise a polycrystalline silicon layer. Then, the polycrystalline silicon layer is planarized (e.g., by CMP) until the upper ends of the third oxide layer spacers 24a are exposed. By doing so, as illustrated in FIG. 12, the floating gate array in which the device isolation layers 22 and the floating gates 26 are self aligned is formed.

Then, an insulating layer such as an ONO dielectric layer 28, used as an insulating layer between the floating gates and a subsequent control gate, is formed (e.g., by CVD when dielectric layer 28 comprises or consists of a silicon oxide layer, or sequential CVD processes in the ONO case). A control gate layer 30 comprising polycrystalline silicon is then formed on the floating gate array 26 insulated by the third oxide layer spacers 24a and the dielectric layer 28. Consequently, the control gate layer 30 can be patterned (e.g., in the row direction), and the flash memory device including the self aligned floating gate array is obtained as illustrated in FIG. 13.

According to the present invention, it is possible to minimize the width of the device isolation regions regardless of the minimum line width as defined by design rules of a given manufacturing process. Therefore, it is possible to make the flash memory cell highly integrated. In particular, in the flash memory cell according to the present invention, since the device isolation layer between adjacent cells may be formed by a thermal oxidation method, the quality of the device isolation layer can be high. Also, the floating gates are formed in the same photolithographic process as the device isolation layer, so that it is possible to obtain a floating gate array in which sidewalls of the flowing gates are self aligned to the device isolation layers.

According to the present invention, since the floating gates are not limited by the minimum line width, it is possible to form a highly integrated flash memory cell array. In particular, the method of forming the self aligned floating gate according to the present invention can be applied to any cell structures (e.g., having the NOR-type structure or the NAND-type structure).

While the invention has been shown and described with reference to certain preferred embodiments thereof, it will be understood by those skilled in the art that various changes in form and details may be made therein without departing from the spirit and scope of the invention as defined by the appended claims.

What is claimed:

1. A method of forming a floating gate array, the method comprising the steps of:
(a) forming a first sacrificial layer pattern on a first oxide layer on a silicon substrate;
(b) forming first spacers on the sidewalls of the first sacrificial layer pattern;
(c) selectively removing the first sacrificial layer pattern;
(d) forming a second sacrificial layer pattern divided by the first spacers;
(e) removing the first spacers to expose the surface of the substrate between the second sacrificial layer pattern;
(f) etching the surface of the exposed substrate to a predetermined depth to form trenches in the substrate;
(g) oxidizing the exposed surface of the substrate to form device isolation layers;
(h) forming second spacers between the second sacrificial layer pattern structures;
(i) selectively removing the second sacrificial layer pattern; and
(j) forming a plurality of floating gates divided by the third oxide layer spacer.

2. The method of claim 1, wherein the first sacrificial layer pattern is formed only in an active device region of two adjacent memory cells.

3. The method of claim 1, wherein forming the second sacrificial layer pattern comprises the steps of:
forming a second sacrificial layer on the substrate; and
planarizing the upper portion of the second sacrificial layer until the upper ends of the first spacers are exposed.

4. The method of claim 1, wherein removing the first spacers comprises a wet etching process.

5. The method of claim 1, wherein oxidizing the exposed surface of the substrate comprises a wet or dry thermal oxidation process.

6. The method of claim 1, wherein selectively removing the second sacrificial layer pattern comprises the steps of:
forming a third spacer material on the substrate to fill gaps in the second sacrificial layer pattern; and
planarizing the third spacer material until the second sacrificial layer pattern is exposed.

7. The method of claim 1, wherein forming the plurality of floating gates comprises the steps of:
depositing a floating gate material on the substrate; and
planarizing the floating gate material until the second spacers are exposed.

8. The method of claim 1, wherein forming the first nitride layer pattern comprises etching the first nitride layer.

9. The method of claim 1, wherein the first sacrificial layer comprises a first nitride layer.

10. The method of claim 1, wherein the first spacers comprise a first oxide.

11. The method of claim 1, wherein forming the second sacrificial layer pattern comprises blanket-depositing the second sacrificial layer sufficiently to fill the spaces between the first spacers.

12. The method of claim 1, wherein forming the plurality of floating gates comprises blanket-depositing polysilicon sufficiently to fill the spaces between the second spacers.

13. The method of claim 1, wherein the second sacrificial layer comprises a second nitride layer.

14. The method of claim 1, wherein the second spacers comprise a second oxide.

15. A flash memory device, comprising:
a plurality of device isolation layers comprising a thermal silicon oxide in a silicon substrate; and
a floating gate array in active device regions divided by the plurality of device isolation layers, and in which sidewalls of each floating gate are self aligned to the device isolation layers.
